(19) United States
(12) Patent Application Publication
(10) Pub. No.: US 2025/0386485 A1
(43) Pub. Date: Dec. 18, 2025

(54) MEMORY DEVICE USING SEMICONDUCTOR DEVICES

(71) Applicant: Unisantis Electronics Singapore Pte. Ltd., Singapore (SG)

(72) Inventors: Masakazu KAKUMU, Tokyo (JP); Iwao KUNISHIMA, Tokyo (JP); Nozomu HARADA, Tokyo (JP)

(21) Appl. No.: 19/224,206

(22) Filed: May 30, 2025

(30) Foreign Application Priority Data
Jun. 3, 2024 (JP) 2024-0089930

(51) Int. Cl. H10B 12/00

(52) U.S. Cl. CPC H10B 12/20

(57) ABSTRACT

There is provided a memory cell in which an n-layer is formed on a p-layer on a substrate, a columnar p-layer is on part of the n-layer extending vertically, an insulating layer covers part of the n-layer, a gate insulating layer is in contact with this insulating layer, a gate conductor layer is in contact with the gate insulating layer and the insulating layer, an insulating layer is in contact with this gate conductor layer, another p-layer is on the p-layer, a gate insulating layer is on the other p-layer, an n+ layers on both ends of the other p-layer, and a gate conductor layer. A MOSFET having all constituent elements of this memory cell except for the n-layer is on the same chip, the same voltages are applied during memory readout to determine the memory content on the basis of a magnitude comparison with the cell current.

### CROSS-REFERENCE TO RELATED APPLICATIONS

This application claims priority to JP2024-089930, filed Jun. 3, 2024, the entire content of which is incorporated herein by reference.

### BACKGROUND OF THE INVENTION

### 1. Field of the Invention

The present invention relates to a memory device using semiconductor devices.

### 2. Description of the Related Art

In recent years, in the development of large scale integration (LSI) technology, there has been a demand for the higher integration, higher performance, lower power consumption, and higher functionality of memory devices that can incorporate logic circuits using semiconductor devices.

Dynamic random access memory (DRAM) is widely used as memory in integrated circuits. In order to increase the density of DRAM memory, there are a DRAM (see, for example, H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical DRAM Cell with Vertical Pillar Transistor (VPT)”, 2011 Proceeding of the European Solid-State Device Research Conference, (2011)) with an SGT structure extending perpendicular to the top surface of the semiconductor substrate (see, for example, Japanese Unexamined Patent Application Publication No. Hei 2-188966, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) and a DRAM memory cell without a capacitor and constituted by a single MOS transistor (see T. Ohsawa, K. Fujita, T. Higashi, Y. Iwata, T. Kajiyama, Y. Asano, and K. Sunouchi, “Memory Design Using a One-Transistor Gain Cell on SOI”, IEEE Journal of Solid State Circuits, Vol. 37, No. 11, pp. 1510-1522 (2002); J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006); and E. Yoshida: “A Capacitorless 1T-DRAM Technology Using Gate-Induced Drain-Leakage (GIDL) Current for Low-Power and High-Speed Embedded Memory”, IEEE IEDM (2006)). This is commonly known as “1TDRAM”. For example, logical memory data “1” is written by retaining, among a group of holes and a group of electrons generated in the channel due to the impact ionization phenomenon caused by the current between the source and drain of an n-channel MOS transistor, part or all of the group of holes in the channel. Then, logical memory data “0” is written by discharging the group of holes from the channel.

There is also a twin-transistor MOS transistor memory device that uses two MOS transistors to form a single memory cell in the silicon-on-insulator (SOI) layer (see, for example, US 2008/0137394 A1, US 2003/0111681 A1, and F. Morishita, H. Noda, I. Hayashi, T. Gyohten, M. Ocksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4, pp. 765-771 (2007)). In addition, there is a dynamic flash memory (DFM) that does not have capacitors and in which a single memory cell is formed with two gate electrodes (see U.S. Pat. No. 11,798,616 B2, and K. Sakui, N. Harada, “Dynamic Flash Memory with Dual Gate Surrounding Gate Transistor (SGT)”, Proc. IEEE IMW, pp. 72-75 (2021)). In this memory cell, by operating the voltages of the four electrodes, the carrier concentration in the floating body is changed to create a conducting or non-conducting state for memory operation. In addition, a structure in which a carrier-holding body is connected to the bottom of a metal oxide semiconductor (MOS) transistor has been proposed (see US 2023/0077140 A1). In these floating body memories, it is difficult and complex to design a circuit to derive the reference voltage and current to determine whether information is written into or erased from the memory cell. In addition, the circuit characteristics vary depending on the expected changes in conditions (voltage and temperature), and thus the margin for that determination is narrow.

### SUMMARY OF THE INVENTION

The purpose of the present invention is to provide, together with memory cells, a device structure for convenient and reliable detection of whether the contents of a memory are in a written state or an erased state.

In order to solve the above problems, a memory device using semiconductor devices according to the present invention includes
a memory cell that includes
a substrate,
a first semiconductor region on the substrate,
a first impurity region on a surface of part of the first semiconductor region,
a second semiconductor region that is in contact with the first impurity region and extends vertically in a columnar shape,
a first insulating layer that covers part of the first impurity region,
a first gate insulating layer that at least partially covers and surrounds a side surface of the second semiconductor region arranged on the first impurity region,
a first gate conductor layer that is on the first insulating layer and in contact with a side surface of the first gate insulating layer,
a second insulating layer that is formed on the first gate conductor layer so as to be in contact with the first gate insulating layer, wherein the second insulating layer and the first gate insulating layer are arranged to insulate the second semiconductor region from the first gate conductor layer,
a third semiconductor region formed on the second semiconductor region,
a second gate insulating layer formed on the third semiconductor region so as to cover part or all of the third semiconductor region,
a second gate conductor layer formed on the second gate insulating layer so as to cover part or all of the second gate insulating layer, and
a second impurity region and a third impurity region that are individually connected to both ends of the third semiconductor region, and
a metal oxide semiconductor field-effect transistor formed on the substrate, the metal oxide semiconductor field-effect transistor having same constituent elements as the memory cell except for the first impurity region and having same design dimensions as the memory cell in plan view, and
the memory device is configured to determine whether the memory is in a written state or an erased state by determining whether a drain current that flows in a case where a voltage applied to a bit line connected to the third impurity region is applied to a drain of the metal oxide semiconductor field-effect transistor and a voltage applied to a word line connected to the second gate conductor layer is applied to a gate of the metal oxide semiconductor field-effect transistor is greater or less than a memory cell read current during memory readout.

Preferably, in the memory device,
the memory cell includes
a first wiring conductor layer connected to the second impurity region,
a second wiring conductor layer connected to the third impurity region,
a third wiring conductor layer connected to the second gate conductor layer,
a fourth wiring conductor layer connected to the first gate conductor layer, and
a fifth wiring conductor layer connected to the first impurity region,
a memory write operation is performed by performing an operation for generating a group of electrons and a group of holes in the third semiconductor region and the second semiconductor region using a gate-induced drain leakage current or through an impact ionization phenomenon caused by a current flowing between the second and third impurity regions by controlling voltages applied to the first, second, third, fourth, and fifth wiring conductor layers, an operation for discharging either the group of electrons or the group of holes serving as minority carriers in the third semiconductor region and second semiconductor region among the generated groups of electrons and holes, and an operation for retaining, in the third semiconductor region and second semiconductor region, part or all of either the group of electrons or the group of holes serving as majority carriers in the third semiconductor region and second semiconductor region, and
an memory erasure operation is performed by extracting either the group of retained electrons or the group of retained holes serving as majority carriers in the second or third semiconductor region from at least one of the first impurity region, the second impurity region, or the third impurity region through recombination with majority carriers in the first, second, and third impurity regions by controlling the voltages applied to the first, second, third, fourth, and fifth wiring conductor layers.

Preferably, in the memory device,
in the memory cell, the first wiring conductor layer connected to the second impurity region is a source line, the second wiring conductor layer connected to the third impurity region is a bit line, the third wiring conductor layer connected to the second gate conductor layer is a word line, the fourth wiring conductor layer connected to the first gate conductor layer is a plate line, the fifth wiring conductor layer is a control line, and voltages are applied to the source line, the bit line, the plate line, the word line, and the control line in an individual manner to perform the memory write operation and the memory erasure operation.

Preferably, in the memory device,
majority carriers in the first impurity region are different from majority carriers in the first semiconductor region.

Preferably, in the memory device,
majority carriers in the second impurity region are same as majority carriers in the first impurity region, and the majority carriers in the second impurity region are different from majority carriers in the first semiconductor region.

Preferably, in the memory device,
majority carriers in the second semiconductor region are same as majority carriers in the first semiconductor region.

Preferably, in the memory device,
majority carriers in the second impurity region and the third impurity region are same as majority carriers in the first impurity region.

Preferably, in the memory device,
a vertical distance from a bottom portion of the third semiconductor region to a top portion of the second impurity region is shorter than a vertical distance from the bottom portion of the third semiconductor region to a bottom portion of the first gate conductor layer.

Preferably, in the memory device,
in a vertical direction, a bottom portion of the first impurity region is positioned lower than a bottom portion of the first insulating layer.

Preferably, in the memory device,
in a vertical direction, an upper surface of the first impurity region is positioned higher than an upper surface of the first insulating layer.

Preferably, in the memory device,
the metal oxide semiconductor field-effect transistor provided on the substrate has same constituent elements as the memory cell except for the first impurity region and the first gate conductor layer and has same design dimensions as the memory cell in plan view.

### BRIEF DESCRIPTION OF THE DRAWINGS

FIGS. 1A and 1B are diagrams illustrating a cross-sectional structure of a memory device using semiconductor devices according to a first embodiment and a cross-sectional structure of a metal oxide semiconductor field-effect transistor (MOSFET) used to determine the content of a memory cell;

FIGS. 2A, 2B, and 2C are diagrams for describing accumulation of hole carriers and cell current during a write operation of the memory device using semiconductor devices according to the first embodiment;

FIGS. 3A, 3B, and 3C are diagrams for describing an erase operation of the memory device using semiconductor devices according to the first embodiment;

FIG. 4 is a diagram illustrating a method for determining, using a proposed n-type metal oxide semiconductor field-effect transistor (nMOSFET), whether the memory cell according to the first embodiment is written or erased;

FIG. 5 illustrates an example of a determination circuit in the memory; and

FIGS. 6A and 6B illustrates cross-sectional structures of additional examples of the nMOSFET using semiconductor devices according to the first embodiment.

### DESCRIPTION OF THE PREFERRED EMBODIMENTS

In the following, the structure, drive system, behavior of accumulated carriers, and signal detection of a memory device using semiconductor devices according to an embodiment of the present invention will be described below with reference to the drawings.

### First Embodiment

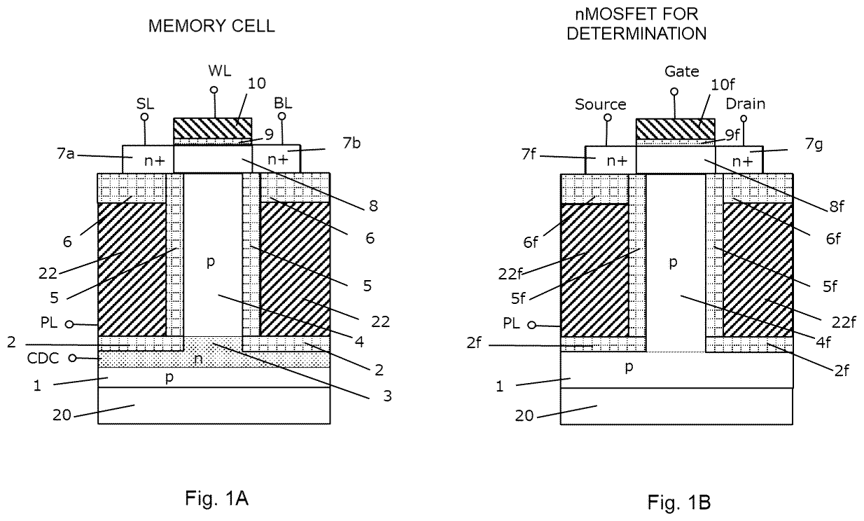

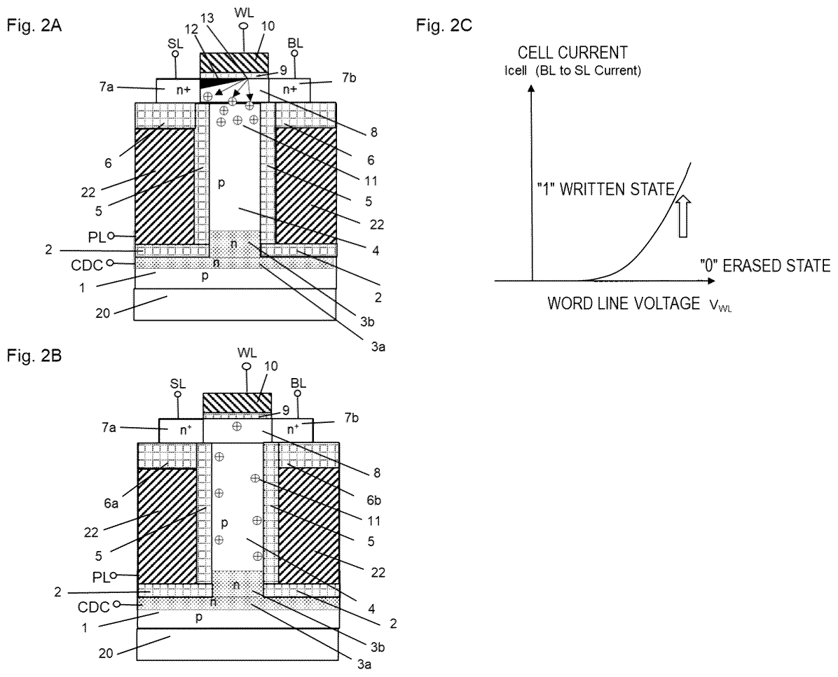

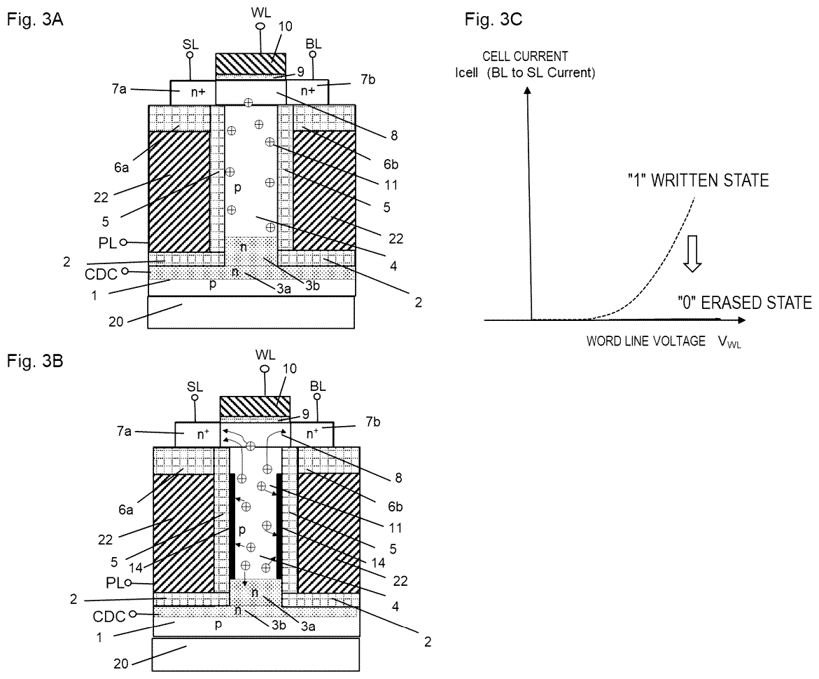

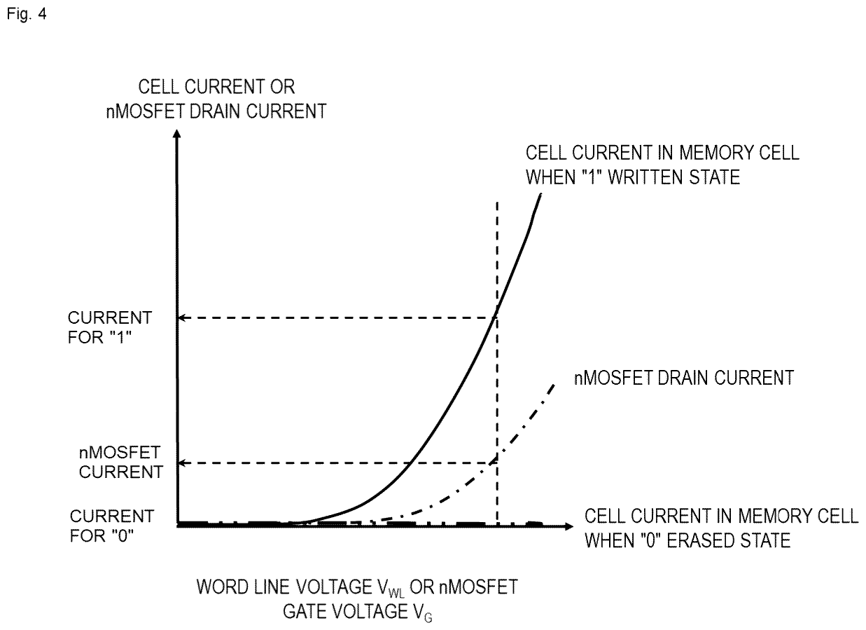

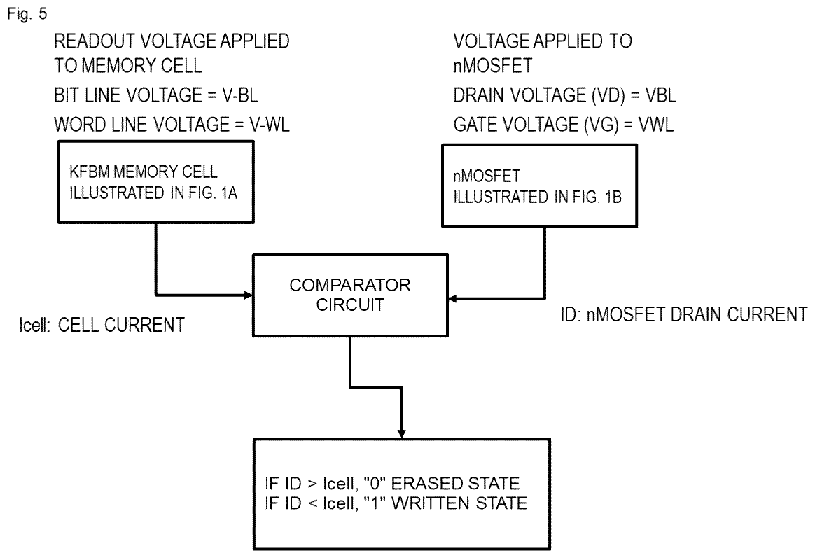

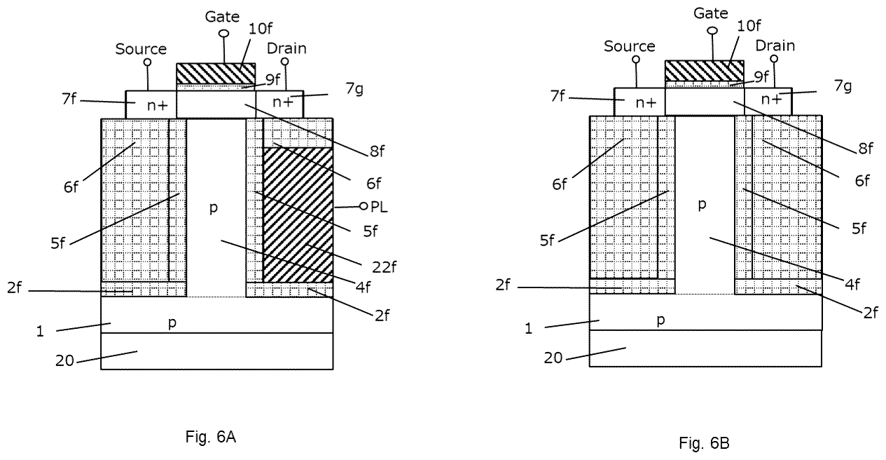

FIG. 1A to FIG. 6B are used to describe the cell structure and operation of a memory using semiconductor devices according to the present embodiment, and the way in which the state of the memory cell is determined using a comparison with the drain current of an n-type metal oxide semiconductor field-effect transistor (nMOSFET) at a voltage applied under the same conditions as the cell readout. FIGS. 1A and 1B are used to describe the cell structure of the memory using semiconductor devices according to the present embodiment and the structure of the nMOSFET used to determine whether the memory is in the written or erased state. FIGS. 2A to 2C are used to describe the write mechanism and carrier behavior of the memory cell using semiconductor devices. FIGS. 3A to 3C are used to describe the memory erase mechanism and carrier behavior. FIG. 4 is used to describe the relationship between the cell current and the current of the nMOSFET for determination during writing and erasing of the memory according to the present embodiment. FIG. 5 is used to describe an example of a circuit configuration for determining the cell contents of the memory according to the present embodiment. FIGS. 6A and 6B are used to describe application examples of the structure of the nMOSFET, which is for determination, according to the present embodiment.

FIG. 1A illustrates a vertical cross-sectional structure of a memory using semiconductor devices according to the embodiment of the present invention. A p-layer 1 (an example of “first semiconductor region” in the claims) of silicon with p-type conductivity containing acceptor impurities is on a substrate 20 (an example of “substrate” in the claims). A semiconductor having an n-layer 3 (an example of “first impurity region” in the claims) containing donor impurities is in contact with the p-layer 1. A columnar p-layer 4 (which is an example of “second semiconductor region” in the claims) having a rectangular horizontal cross-section and containing acceptor impurities is in contact with the n-layer 3. A first insulating layer 2 (an example of “first insulating layer” in the claims) covers part of the p-layer 1, n-layer 3, and p-layer 4. A first gate insulating layer 5 (an example of “first gate insulating layer” in the claims) is arranged on and in contact with the first insulating layer 2 and covers a side surface of the columnar p-layer 4. Moreover, a first gate conductor layer 22 (an example of “first gate conductor layer” in the claims) is arranged on the first insulating layer 2 and is in contact with a side surface of the first gate insulating layer 5. As a result, the first gate conductor layer 22 surrounds all or part of the perimeter of the p-layer 4. A second insulating layer 6 (an example of “second insulating layer” in the claims) is arranged so as to be in contact with an upper side surface of the first gate insulating layer 5 and on and in contact with the first gate conductor layer 22. A p-layer 8 (an example of “third semiconductor region” in the claims) containing acceptor impurities is in contact with the p-layer 4.

An n+ layer 7a (an example of “second impurity region” in the claims) and an n+ layer 7b (an example of “third impurity region” in the claims) containing donor impurities are electrically insulated from each other by being in contact with both ends of the p-layer 8 in the horizontal direction (hereinafter semiconductor regions containing high concentrations of donor impurities are referred to as “n+ layers”).

A second gate insulating layer 9 (an example of “second gate insulating layer” in the claims) is on the upper surface of the p-layer 8. The second gate insulating layer 9 is in contact with or near each of the n+ layers 7a and 7b. A second gate conductor layer 10 (an example of “second gate conductor layer” in the claims) is on the second gate insulating layer 9 in the vertical direction.

In FIG. 1A, the boundary line between the n-layer 3 and the p-layer 4 is drawn so as to coincide with the upper surface of the first insulating layer 2. However, this boundary line may be above or below the upper surface of the first insulating layer 2. Moreover, the upper portion of the p-layer 4 is covered by the first gate insulating layer 5, but for fabrication convenience, the upper portion of the p-layer 4 may be in contact with the second insulating layer 6. In this regard, it is sufficient that the first insulating layer 2, first gate insulating layer 5, and second insulating layer 6 be arranged so as to insulate the n-layer 3 and p-layer 4 from the first gate conductor layer 22. For example, the first gate insulating layer 5 may cover all but the upper side surface of the p-layer 4 (cover at least part of the side surface of the p-layer 4), and the second insulating layer 6, instead of the first gate insulating layer 5, may directly cover the upper side surface of the p-layer 4. Moreover, the first gate insulating layer 5 may be arranged directly on the n-layer 3 so as to directly cover the n-layer 3. In this case, the second insulating layer 6, together with the first gate insulating layer 5, insulates the upper side surface of the p-layer 4 from the first gate conductor layer 22. The first insulating layer 2, together with the first gate insulating layer 5, insulates the n-layer 3 and the lower side surface of the p-layer 4 from the first gate conductor layer 22.

As a result, a memory device using semiconductor devices is formed, the semiconductor devices including the substrate 20, the p-layer 1, the first insulating layer 2, the first gate insulating layer 5, the first gate conductor layer 22, the second insulating layer 6, the n-layer 3, the p-layer 4, the n+ layer 7a, the n+ layer 7b, the p-layer 8, the second gate insulating layer 9, and the second gate conductor layer 10. The n+ layer 7a is connected to a source line SL, which is a first wiring conductive layer (an example of “source line” in the claims). The n+ layer 7b is connected to a bit line BL, which is a second wiring conductive layer (an example of “bit line” in the claims). The second gate conductor layer 10 is connected to a word line WL, which is a third wiring conductive layer (an example of “word line” in the claims). The first gate conductor layer 22 is connected to a plate line PL, which is a fourth wiring conductive layer (an example of “plate line” in the claims). The n-layer 3 is connected to a control line CDC, which is a fifth wiring conductive layer (an example of “control line” in the claims). The memory is operated by operating the voltages applied to the source line SL, bit line BL, plate line PL, word line WL, and control line CDC. This memory device is hereinafter referred to as Key shape Floating Body Memory (KFBM).

FIG. 1B illustrates a cross-sectional view of an nMOSFET used in memory cell determination according to the present embodiment. In the signs indicating the constituent elements of the nMOSFET, each numeral that is the same as that of the memory cell illustrated in FIG. 1A indicates that they are formed by the same layer. The constituent elements having the same numerals indicate that the film thicknesses, impurity concentrations, profiles, planar dimensions, and vertical dimensions are the same as the design dimensions of the memory. However, the only difference between the memory and the nMOSFET is that the nMOSFET does not have the n-layer 3 of the memory cell. As described below, the characteristics of this nMOSFET are used to determine whether the memory cell is written or erased.

In the actual memory device according to the present embodiment, one KFBM memory cell illustrated in FIG. 1A is arranged on the substrate 20, or multiple KFBM memory cells illustrated in FIG. 1A are arranged in a two-dimensional manner on the substrate 20. The nMOSFET illustrated in FIG. 1B is arranged in a region surrounding the memory cell or memory cells and used to determine the memory content.

Although the p-layer 1 is a p-type semiconductor in FIGS. 1A and 1B, the impurity concentration may have a profile. The impurity concentrations in the n-layer 3, the p-layer 4, and the p-layer 8 may have profiles. The p-layer 4 and p-layer 8 may be set independently of each other in terms of impurity concentration and profile. The p-layer 4 and p-layer 8 may be formed of different semiconductor material layers. In plan view, the cross-section of the p-layer 4 may have the same shape as the connection surface of the p-layer 4 and p-layer 8. Alternatively, the length of the p-layer 8 in the horizontal direction may be longer or shorter than the width of the p-layer 4 in the direction in which the p-layer 8 is connected to the n+ layers 7a and 7b. A lightly doped drain (LDD) region having a donor concentration lower than the donor impurity concentrations of the n+ layers 7a and 7b may be provided between the p-layer 8 and the n+ layers 7a and 7b. Note that, the greater the thickness of the p-layer 4 compared with the thickness of the p-layer 8, the higher the retention capability of this memory becomes. In other words, the longer the distance from the bottom portion of the p-layer 8 to the top portion of the n+ layer 7a or n+ layer 7b compared with the distance from the bottom portion of the p-layer 8 to the bottom portion of the first gate conductor layer 22, the higher the retention performance of the memory becomes.

In FIGS. 1A and 1B, the first insulating layer 2 and the first gate insulating layer 5 are illustrated separately; however, the first insulating layer 2 and the first gate insulating layer 5 may be formed so as to be integrated with each other. In the following, the first insulating layer 2 and the first gate insulating layer 5 are also collectively referred to as “first gate insulating layer 5”.

In FIGS. 1A and 1B, the p-layer 8 is a p-type semiconductor; however, the p-layer 8 can be of p-type, n-type, or i-type, depending on the majority carrier concentration in the p-layer 4, the thickness of the p-layer 8, the material and thickness of the second gate insulating layer 9, and the material of the second gate conductor layer 10.

The substrate 20 can be an insulator, semiconductor, conductor, or any material that can support the p-layer 1.

The first through fifth wiring conductive layers may be formed in multiple layers as long as the first through fifth wiring conductive layers are not in contact with each other.

For the first and second gate insulating layers 5 and 9, any insulating film used in a normal MOS process can be used. Examples of such an insulating film include an SiO₂ film, an SiON film, an HfSiON film, or an SiO₂/SiN laminated film, for example.

As long as the first gate conductor layer 22 can change the potential of part of the memory cell through the first gate insulating layer 5, and the second gate conductor layer 10 can change the potential of part of the memory cell through the second gate insulating layer 9, the first and second gate insulating layers 5 and 9 may be made of a metal or a metal nitride such as W, Pd, Ru, Al, TiN, TaN, or WN, or alloy thereof (including silicide). For example, the first and second gate insulating layers 5 and 9 may have a laminated structure such as TiN/W/TaN or may be formed of a heavily doped semiconductor.

In FIGS. 1A and 1B, the memory cell and the nMOSFET are described as including the p-layer 4 and p-layer 8 having a rectangular cross-sectional structure perpendicular to the paper surface; however, the p-layer 4 and p-layer 8 may have a trapezoidal or polygonal cross-sectional structure or, in plan view, the cross-section of the p-layer 4 may be circular or oval.

A MOSFET including the n+ layers 7a and 7b, the p-layer 8, the second gate insulating layer 9, and the second gate conductor layer 10 may be of a planar FET or a fin (Fin) FET. In a planar FET, the second gate insulating layer 9 is formed on the upper surface of the p-layer 8, and the second gate conductor layer 10 is formed on the second gate insulating layer 9. In a fin FET, the second gate insulating layer 9 is formed on the upper surface and both side surfaces of the p-layer 8, and the second gate conductor layer 10 is formed so as to cover the second gate insulating layer 9. An FET may also be used in which the p-layer 8 serving as a channel is U-shaped.

The first insulating layer 2, the second insulating layer 6, and the first gate insulating layer 5 can be formed at the same time and can be formed using the same material. The voltage applied to the first gate conductor layer 22 can be adjusted by adjusting the thickness of each of the first gate insulating layer 5 and the first and second insulating layers 2 and 6.

In FIG. 1A, the first gate conductor layer 22 may surround all or part of the p-layer 4 in plan view. The first gate conductor layer 22 may be divided into multiple sections in plan view. The first gate conductor layer 22 may be divided in multiple sections in the vertical direction. In the cross-sectional structure, the first gate conductor layer 22 is present on both sides of the p-layer 4 in FIG. 1A; however, as long as the first gate conductor layer 22 is present on either side of the p-layer 4, this also allows KFBM operation.

With reference to FIGS. 2A to 2C, the carrier behavior, charge accumulation, and cell current of the KFBM according to the first embodiment of the present invention and illustrated in FIG. 1A during a write operation (an example of “write operation” in the claims) will be described. First, a case will be described in which the majority carriers in the n-layer 3 and n+ layers 7a and 7b are electrons, for example, polycrystalline silicon (poly-Si) containing a high concentration of donor impurities is used in the first gate conductor layer 22, which is connected to the plate line PL, and the second gate conductor layer 10, which is connected to the word line WL, (hereinafter, poly-Si containing a high concentration of donor impurities will be referred to as “n+ poly”), and a p-type semiconductor is used as the third semiconductor region 8. As illustrated in FIG. 2A, the MOSFET in this memory cell includes, as its constituent elements, the n+ layer 7a serving as the source, the n+ layer 7b serving as the drain, the second gate insulating layer 9, the second gate conductor layer 10 serving as the gate, and the p-layer 8 serving as the substrate, and operates. For example, 0 V is applied to the p-layer 1. For example, 0.5 V is applied to the n-layer 3 to which the control line CDC is connected. For example, 0 V is applied to the n+ layer 7a to which the source line SL is connected. For example, 1.2 V is applied to the n+ layer 7b to which the bit line BL is connected. For example, −1 V is applied to the first gate conductor layer 22 to which the plate line PL is connected. In this case, when the voltage of the plate line PL is −1 V, the threshold of the MOSFET, in which the second gate conductor layer 10 is the gate electrode, before writing is 1.0 V, for example. Next, when 1.5 V, for example, is applied to the second gate conductor layer 10 to which the word line WL is connected, a partial inversion layer 12 is formed directly below the second gate insulating layer 9 under the second gate conductor layer 10, and a pinch-off point 13 exists. Thus, the MOSFET, which has the second gate conductor layer 10, operates in the saturation region.

As a result, the electric field becomes maximum in the boundary region between the pinch-off point 13 and the n+ layer 7b in the MOSFET, which has the second gate conductor layer 10, and the impact ionization phenomenon occurs in this region. This impact ionization phenomenon causes electrons accelerated from the n+ layer 7a, to which the source line SL is connected, to the n+ layer 7b, to which the bit line BL is connected, to collide with the Si lattice, and their kinetic energy generates electron-hole pairs. The generated holes diffuse toward the region with the lower hole concentration due to the concentration gradient. Some of the generated electrons flow to the second gate conductor layer 10, but most of the generated electrons flow to the n+ layer 7b, which is connected to the bit line BL. As a result, a group of holes 11 accumulates in the p-layer 4 and the p-layer 8.

In the above example, −1 V is applied to the plate line PL. This contributes to preventing the depletion layer from spreading into the p-layer and to accumulate holes generated by impact ionization.

In the above example, n+ poly is used in the first gate conductor layer 22 to bias a negative voltage, but a material with a higher work function compared to the material of the second gate conductor layer 10 can be used to produce substantially the same effect as applying a negative voltage.

Instead of causing the impact ionization phenomenon described above, a gate-induced drain leakage (GIDL) current may be caused to flow to generate a group of holes (see, for example, F. Morishita, H. Noda, I. Hayashi, T. Gyohten, M. Ocksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4, pp. 765-771 (2007)).

FIG. 2B illustrates the group of holes 11 in the p-layers 4 and 8 when the plate line PL becomes −1 V, the biases of the word line WL, source line SL, and bit line BL become 0 V, and the bias of the control line CDC becomes 0.5 V immediately after writing. The generated group of holes 11 serves as the majority carriers in the p-layers 4 and 8. The concentration of the generated holes is temporarily high in the region of the p-layer 8, and the holes move toward the p-layer 4 through diffusion due to the concentration gradient. Furthermore, a high concentration of holes is accumulated in the vicinity of the first gate insulating layer 5 of the p-layer 4 to apply a negative potential to the first gate conductor layer 22. The p-layers 4 and 8 are electrically connected to each other, which in effect charges the p-layer 8, which is the substrate of the MOSFET having the second gate conductor layer 10, to a positive bias. The threshold voltage of the MOSFET having the second gate conductor layer 10 is lowered by the positive substrate bias effect due to the holes temporarily stored in the p-layers 4 and 8. In the case of this example, the threshold of the MOSFET after writing becomes 0.6 V. As a result, as illustrated in FIG. 2C, the threshold voltage of the MOSFET having the second gate conductor layer 10, to which the word line WL is connected, becomes about 0.3 V, which is lower than before writing. This written state is assigned to logical memory data “1”. This is the so-called “written” state.

According to the structure of the present embodiment, the p-layer 8 of the MOSFET having the second gate conductor layer 10, to which the word line WL is connected, is electrically connected to the p-layer 4, and thus the capacitance for accumulating the generated holes can be freely changed by the volume of the p-layer 4.

In addition to the example described above, for example, when the voltage applied to the bit line BL, the voltage applied to the plate line PL, and the voltage applied to the word line WL are abbreviated as V-BL, V-PL, and V-WL, respectively, a combination of 1.0 V (V-BL), −1 V (V-PL), and 2.0 V (V-WL), a combination of 1.0 V (V-BL), −0.5 V (V-PL), and 1.2 V (V-WL), a combination of 1.5 V (V-BL), −1 V (V-PL), and 2.0 V (V-WL), and other combinations are also possible as voltage application conditions, assuming SL is at 0 V. The voltage relationship between the bit line BL and the source line SL may be switched. Note that in a case where 1.0 V is applied to the bit line BL, 0 V is applied to the source line SL, 2 V is applied to the word line WL, and −1 V is applied to the plate line PL, the threshold value drops during writing, the pinch-off point 13 gradually shifts toward the n+ layer 7b, and the MOSFET may operate in the linear region.

Next, the mechanism of an erase operation (which is an example of “erase operation” in the claims) will be described using FIGS. 3A to 3C. FIG. 3A illustrates the state immediately after the group of holes 11 generated by impact ionization in the previous cycle is stored in the p-layers 4 and 8 before the erase operation. The voltages of the source line SL, bit line BL, and control line CDC are 0.5 V, and the voltage of the plate line PL is −1 V.

As illustrated in FIG. 3B, during the erase operation, the voltages of the source line SL, bit line BL, and word line WL are set to 0 V, and the voltage of the control line CDC is set to 0.5 V. The voltage of the plate line PL is set to, for example, 2 V. As a result, regardless of the value of the initial potential of the p-layer 8, an inversion layer 14 of electrons is formed at the interface between the first gate insulating layer 5 and the p-layer 4. Part of this inversion layer 14 is in contact with the n-layer 3. Thus, the holes accumulated in the p-layer 4 flow from the p-layer 4 to the inversion layer 14 and recombine with electrons. The electrons lost through recombination are replaced by electrons through the n-layer 3 from the inversion layer 14, which is in contact with the n-layer 3. In FIG. 3B, the inversion layer 14 is illustrated as being divided into left and right sections, but since the inversion layer 14 is formed at the periphery of the p-layer 4, the left and right sections are electrically connected and will not be affected by the smaller contact area between the p-layer 4 and the n-layer 3b. As a result of this recombination of holes and electrons, the concentration of holes in the p-layers 4 and 8 decreases with time, and the threshold voltage of the MOSFET becomes higher than when “1” was written. For example, in this case, when the voltage of the plate line PL is −1 V, the threshold of the MOSFET is 1.2 V. As a result, as illustrated in FIG. 3C, the threshold of the MOSFET having the second gate conductor layer 10, to which this word line WL is connected, returns to its original threshold. This erased state of the KFBM is assigned to logical memory data “0”. This is the so-called “erased” state.

According to the structure of the present embodiment, the area where electrons and holes recombine can be effectively increased during data erasure compared with that under voltage conditions outside of data erasure. Thus, a stable state where the logical memory data is “0” can be provided in a short time, and the operation speed of this KFBM is improved. The power consumption during data erasure is almost equal to the total amount of holes accumulated in the p-layers 4 and 8, and no other current flows. Thus, a significant reduction in power consumption can be achieved.

As a data erasure method other than the example described above, when the voltage applied to the bit line BL, the voltage applied to the plate line PL, and the voltage applied to the word line WL are abbreviated as V-BL, V-PL, and V-WL, respectively, a combination of 0 V (V-BL), 2 V (W-PL), and −1 V (V-WL), a combination of 0.4 V (V-BL), 2 V (V-PL), and 0.5 V (V-WL), a combination of 1 V (V-BL), 1.5 V (V-PL), 0 V (V-WL), and other combinations are possible as voltage application conditions, assuming the source line SL is at 0 V and the control line CDC is at 0.5 V. Voltage conditions applied to the bit line BL, the source line SL, the word line WL, and the plate line PL are examples for the memory erasure operation, and other operation conditions that enable the memory erasure operation may also be used.

The description has been made in which the control line CDC is at 0.5 V during both memory writing and erasure; however, the control line CDC can also be set to ground voltage, namely 0 V.

Next, FIG. 4 is used to describe the relationship between the cell current and the drain current of the nMOSFET used for determination during writing and erasure. This diagram illustrates the relationship between the word line WL voltage and the cell current when the cell is read out after writing “1” illustrated in FIG. 2C, and the relationship between the word line WL voltage and the cell current when the cell is erased to “0” illustrated in FIG. 3C. FIG. 4 also illustrates the relationship between drain current and gate voltage VG when the drain voltage VD is applied that is equivalent to the bit line voltage during cell readout of the nMOSFET illustrated in FIG. 1B.

As is apparent from FIG. 4, in a case where the voltage under the same conditions as when reading out the memory cell is applied to the nMOSFET, that is, in a case where the same voltage V-BL as that used when reading out the memory cell is applied as the drain voltage VD and the same voltage as V-WL is applied as the gate voltage VG, a drain current ID flowing in the nMOSFET will always be between the cell read currents “1” and “0”. Thus, by comparing the cell current with the current flowing in the nMOSFET having the cross-sectional structure illustrated in FIG. 1B, it is possible to determine whether the memory cell is in the written state indicated by “1” or the erased state indicated by 0″.

According to the present embodiment, even if the temperature during memory cell operation changes or the readout voltage applied to the memory cell changes, the cell current of the memory and the drain current of the nMOSFET vary in coordination, moving similarly in both the increasing and decreasing directions, and thus the relationship between these currents remains always the same. In addition, even if the gate oxide film thickness and impurity concentration change during manufacturing and are distributed, the cell current and nMOSFET drain current still change in coordination with each other, and thus this relationship remains the same. Therefore, the content of the memory cell can be determined with a large margin without changing the relationship between these currents for any variations in the operating environment and any variations in manufacturing.

Next, FIG. 5 is used to illustrate an example of the way in which the state of the memory cell is determined in an actual circuit. Let the cell current flowing when the memory cell readout voltage, bit line voltage V-BL, and word line voltage V-WL are applied be denoted as Icell. At this time, the same voltage as V-BL is applied as the drain voltage VD of the nMOSFET, the same voltage as V-WL is applied as the gate voltage VG of the nMOSFET, and the current flowing is denoted as ID. A current comparison circuit is used to determine which of Icell and ID is higher, and in a case where Icell is higher than ID, the state is determined to be the written state “1”, and in a case where Icell is lower than ID, the state is determined to be the erased state “0”. The current comparison circuit can be any circuit widely used in practice. As a matter of course, it is acceptable to convert the current into a voltage and make a determination based on the magnitude of the voltage.

Although this comparison circuit is arranged in the peripheral circuit of the memory cell, it does not require complex circuitry, allowing the design of the determination circuit in a small area and contributing to higher memory density.

FIGS. 6A and 6B are used to describe an additional example of the nMOSFET in FIG. 1B. In FIGS. 6A and 6B, the same or similar structural elements as in FIG. 1B are denoted by the same numerical signs. As illustrated in FIG. 6A, the first gate conductor layer 22 in FIG. 1B is present only on one side. In FIG. 6B, the first gate conductor layer 22 is not present and is replaced with the second insulating layer 6 instead. Otherwise, FIGS. 6A and 6B are the same as FIG. 1B. Even when such an nMOSFET is used, the determination of “1” and “0” for the memory cell can be made in the same manner. Even with such a structure, the relationship with the cell current illustrated in FIG. 4 is maintained.

As is apparent from the structures illustrated in FIGS. 1A and 1B, the device structures including the p-layer 8, the n+ layers 7a and 7b, the second gate insulating layer 9, and the second gate conductor layer 10 can be formed not only in this memory cell but also in other MOS circuits including other general CMOS structures. For example, the p-layers 1, 4, and 8 can be shared as part of the CMOS structure. Thus, this memory cell can be easily combined with existing CMOS circuits.

In FIGS. 1A and 1B, the first semiconductor region 1 is a p-type semiconductor; however, the KFBM will still operate even when an n-type semiconductor substrate is used as the substrate 20, a p-well is formed, and this is used as the first semiconductor region 1 to arrange the memory cell according to the present invention.

The memory cell according to the present invention is formed in the area of a single MOSFET in plan view, and thus its source and bit lines can be shared with adjacent memory cells to achieve a higher density memory cell array than existing dynamic RAMS.

In a case where the n+ layers 7a and 7b are formed using a p+ layer in which holes are the majority carriers (hereinafter a semiconductor region containing a high concentration of acceptor impurities will be referred to as “p+ layer”), if the p-layers 1, 4, and 8 are made of n-type semiconductors and the n-layer 3 is made of a p-type semiconductor, the KFBM operates with electrons as the carriers for writing.

Moreover, in the present embodiment, the example has been described in which the p-layers 4 and 8 are formed perpendicular to the substrate 20, but the present invention can also be applied to the case where the p-layers 4 and 8 are formed in the horizontal direction with respect to the substrate 20.

The present embodiment has the following features.

### Feature 1

The KFBM according to the first embodiment of the present invention includes the second gate conductor layer 10, the first gate conductor layer 22, the first insulating layer 2, and the p-layers 4 and 8 surrounded by the first gate insulating layer 5, the n-layer 3, and the n+ layers 7a and 7b. By changing the applied voltages, the written and erased states can be switched by accumulating or removing holes in the p-layer 4 and p-layer 8. Then, by using an nMOSFET having the same structure as the memory cell and comparing its drain current with the cell current, it is possible to determine whether the memory cell is in the written state or the erased state.

### Feature 2

By comparing the drain current of the nMOSFET and the cell current during readout of the KFBM according to the first embodiment of the present invention, determinations can be made independent of environmental changes such as operating voltage and temperature. Furthermore, determinations are not affected by fluctuations in memory cell dimensions, impurity concentration, film thickness, and other factors in KFBM. That is, according to the present invention, a large margin of KFBM operating voltage can be designed.

### Feature 3

The memory cell and nMOSFET, which is for making determinations, according to the first embodiment of the present invention are generated at the same timing, and any additional process is not required.

### Feature 4

The KFBM according to the first embodiment of the present invention can provide high-density memory cell arrays and CMOS-compatible structures.

The use of the semiconductor devices according to the present invention makes it possible to provide semiconductor memory devices with higher density, faster operation, and larger operating margins than existing devices.

What is claimed is:

1. A memory device using semiconductor devices, comprising:
a memory cell that includes
a substrate,
a first semiconductor region on the substrate,
a first impurity region on a surface of part of the first semiconductor region,
a second semiconductor region that is in contact with the first impurity region and extends vertically in a columnar shape,
a first insulating layer that covers part of the first impurity region,
a first gate insulating layer that at least partially covers and surrounds a side surface of the second semiconductor region arranged on the first impurity region,
a first gate conductor layer that is on the first insulating layer and in contact with a side surface of the first gate insulating layer,
a second insulating layer that is formed on the first gate conductor layer so as to be in contact with the first gate insulating layer, wherein the second insulating layer and the first gate insulating layer are arranged to insulate the second semiconductor region from the first gate conductor layer,
a third semiconductor region formed on the second semiconductor region to be in contact with the second semiconductor region,
a second gate insulating layer formed on the third semiconductor region so as to cover part or all of the third semiconductor region,
a second gate conductor layer formed on the second gate insulating layer so as to cover part or all of the second gate insulating layer, and
a second impurity region and a third impurity region that are individually connected to both ends of the third semiconductor region; and
a metal oxide semiconductor field-effect transistor formed on the substrate, wherein the metal oxide semiconductor field-effect transistor does not have, compared with the memory cell, a constituent element corresponding to the first impurity region, has same constituent elements as the memory cell except for the first impurity region, and has same design dimensions as the memory cell in plan view, wherein
the memory device is configured to determine whether the memory is in a written state or an erased state by determining whether a drain current that flows in a case where a voltage applied to a bit line connected to the third impurity region is applied to a drain of the metal oxide semiconductor field-effect transistor, which is a constituent element corresponding to the third impurity region, and a voltage applied to a word line connected to the second gate conductor layer is applied to a gate of the metal oxide semiconductor field-effect transistor, which is a constituent element corresponding to the second gate conductor layer, is greater or less than a memory cell read current during memory readout.

2. The memory device using semiconductor devices according to claim 1, wherein
the memory cell includes
a first wiring conductor layer connected to the second impurity region,
a second wiring conductor layer connected to the third impurity region,
a third wiring conductor layer connected to the second gate conductor layer,
a fourth wiring conductor layer connected to the first gate conductor layer, and
a fifth wiring conductor layer connected to the first impurity region,
a memory write operation is performed by performing an operation for generating a group of electrons and a group of holes in the third semiconductor region and the second semiconductor region using a gate-induced drain leakage current or through an impact ionization phenomenon caused by a current flowing between the second and third impurity regions by controlling voltages applied to the first, second, third, fourth, and fifth wiring conductor layers, an operation for discharging either the group of electrons or the group of holes serving as minority carriers in the third semiconductor region and second semiconductor region among the generated groups of electrons and holes, and an operation for retaining, in the third semiconductor region and second semiconductor region, part or all of either the group of electrons or the group of holes serving as majority carriers in the third semiconductor region and second semiconductor region, and
an memory erasure operation is performed by extracting either the group of retained electrons or the group of retained holes serving as majority carriers in the second or third semiconductor region from at least one of the first impurity region, the second impurity region, or the third impurity region through recombination with majority carriers in the first, second, and third impurity regions by controlling the voltages applied to the first, second, third, fourth, and fifth wiring conductor layers.

3. The memory device using semiconductor devices according to claim 2, wherein
in the memory cell, the first wiring conductor layer connected to the second impurity region is a source line, the second wiring conductor layer connected to the third impurity region is a bit line, the third wiring conductor layer connected to the second gate conductor layer is a word line, the fourth wiring conductor layer connected to the first gate conductor layer is a plate line, the fifth wiring conductor layer is a control line, and voltages are applied to the source line, the bit line, the plate line, the word line, and the control line in an individual manner to perform the memory write operation and the memory erasure operation.

4. The memory device using semiconductor devices according to claim 1, wherein majority carriers in the first impurity region are different from majority carriers in the first semiconductor region.

5. The memory device using semiconductor devices according to claim 1, wherein majority carriers in the second impurity region are same as majority carriers in the first impurity region, and the majority carriers in the second impurity region are different from majority carriers in the first semiconductor region.

6. The memory device using semiconductor devices according to claim 1, wherein majority carriers in the second semiconductor region are same as majority carriers in the first semiconductor region.

7. The memory device using semiconductor devices according to claim 1, wherein majority carriers in the second impurity region and the third impurity region are same as majority carriers in the first impurity region.

8. The memory device using semiconductor devices according to claim 1, wherein a vertical distance from a bottom portion of the third semiconductor region to a bottom portion of the first gate conductor layer is longer than a vertical distance from the bottom portion of the third semiconductor region to a top portion of the second impurity region.

9. The memory device using semiconductor devices according to claim 1, wherein, in a vertical direction, a bottom portion of the first impurity region is positioned lower than a bottom portion of the first insulating layer.

10. The memory device using semiconductor devices according to claim 1, wherein, in a vertical direction, an upper surface of the first impurity region is positioned higher than an upper surface of the first insulating layer.
